(19) United States
(12) Patent Application Publication
(10) Pub. No.: US 2008/0173399 A1
(43) Pub. Date: Jul. 24, 2008

(54) PLASMA PROCESSING APPARATUS COMPONENT AND MANUFACTURING METHOD THEREOF

(75) Inventor: Yusuke NAKAGAWA, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/016,515

(22) Filed: Jan. 18, 2008

Related U.S. Application Data
(60) Provisional application No. 60/912,798, filed on Apr. 19, 2007.

(30) Foreign Application Priority Data
Jan. 22, 2007 (JP) 2007-011435

(51) Int. Cl. H01L 21/306

(52) U.S. Cl. 156/345.1

(57) ABSTRACT

It is intended to minimize the extent of component deterioration occurring during a dry-cleaning process while maintaining the physical characteristics of the component as a whole. Surface fluoridation processing is executed to substitute fluorine for hydrogen bonded to carbon in a surface layer t of an organic material formed in the shape of a component (e.g., a shield ring) to be disposed inside a processing chamber of a plasma processing apparatus and includes a carbon-hydrogen bond.

### CROSS-REFERENCE TO RELATED APPLICATIONS

This document claims priority to Japanese Patent Application Number 2007-011435, filed on Jan. 22, 2007 and U.S. Provisional Application No. 60/912,798, filed on Apr. 19, 2007, the entire content of which are hereby incorporated by reference.

### FIELD OF THE INVENTION

The present invention relates to a component installed in a processing chamber of a plasma processing apparatus and a manufacturing method that may be adopted when manufacturing the component.

### BACKGROUND OF THE INVENTION

As a specific type of processing such as etching is executed on a substrate such as a wafer inside a processing chamber, reaction products (deposit) become adhered to surfaces inside the processing chamber. In order to ensure that such reaction products do not adversely affect subsequent etching processes, the inside of the processing chamber is dry-cleaned with specific timing. Reaction products constituted of a CF polymer having settled onto the surfaces in the processing chamber may be eliminated through, for instance, a dry-cleaning process executed by charging the processing chamber with oxygen gas and raising it to plasma.

There is an issue to be addressed particularly when a component such as an O-ring or a bolt installed in the processing chamber is constituted with an organic resin (e.g., a polyimide resin) or organic rubber (e.g., a fluorocarbon rubber) that includes a carbon-hydrogen bond (C—H), in that the component itself deteriorates as the reaction products are eliminated through the dry-cleaning process.

Even if the dry-cleaning process is executed with oxygen radicals (O*) by using oxygen gas only, a trace amount of fluorine radicals (F*) will be formed as the CF polymer in the processing chamber is forced out. The tests and the like conducted by the inventor of the present invention et al. have confirmed that the presence of the trace amount of fluorine radicals mixed with the oxygen radicals hastens the process of deterioration of a component constituted of an organic material that includes a carbon-hydrogen bond (C—H) to a greater extent than a dry-cleaning process executed exclusively with oxygen radicals.

The significant deterioration that occurs at the organic resin or rubber is assumed to be attributable to the reactive site reaction of the fluorine radicals to the bond between carbon and hydrogen and the reaction of the oxygen radicals to free radicals, which become dominant as the organic resin or rubber is exposed to the oxygen radicals and the trace amount of fluorine radicals formed in the dry-cleaning process.

Since a bolt holding fast a member, for instance, constituted of a polyimide resin, will deteriorate every time the dry-cleaning process is executed under such circumstances, the bolt itself will have to be replaced with optimal timing so as to ensure that the member held by the bolt never becomes loose.

If the bolt is constituted of, for instance, Teflon® resin without a carbon-hydrogen bond (C—H), the component may not deteriorate significantly through the dry-cleaning process. However, the Teflon® resin normally does not assure sufficient strength and thus is not suitable for components that require a high level of strength such as bolts. In addition, the Teflon® resin is normally fairly expensive and thus, the cost of components manufactured by using it is bound to be high.

The extent of deterioration of a member such as an O-ring through the dry-cleaning process may be lessened by forming the O-ring with, for instance, a fully fluoridated rubber that includes almost no carbon-hydrogen bond (C—H). However, the fully fluoridated rubber, which assumes physical characteristics close to those of the Teflon® material, does not provide the desired level of shield and also, since it is expensive, the manufacturing costs are bound to rise as well.

It is to be noted that Japanese Laid Open Patent Publication No. 2004-137349 discloses a rubber product manufacturing method conceived to achieve an object of reducing the tackiness of a rubber product by placing a fluorine-containing monomer gas assuming a plasma state in contact with a rubber material used to manufacture the rubber product and forming a polymerized layer constituted with the fluorine-containing monomer at the surface of the rubber material. However, the polymerized layer of fluorine-containing monomer is formed at the surface of the rubber material through an addition reaction in the method described above, which gives rise to a concerned that, depending upon the thickness of the polymerized layer, the dimensions of the rubber material used to manufacture the rubber product may become greater than predetermined dimensions. In addition, depending upon the shape of the rubber material, it is not always easy to add a polymerized layer of the fluorine-containing monomer evenly over the surface of the rubber material, giving rise to a concern that the shape of the rubber material after the addition reaction may be different from that of the the pre-reaction rubber material,

Japanese Laid Open Patent Publication No. 2005-233339 discloses a composite seal member constituted as an integrated unit assuming a laminated structure achieved by bonding a fluoroelastomer and a parfluoroelastomer via a fluorine resin film. However, the presence of the fluorine resin film and the adhesive between the fluoroelastomer and the parfluoroelastomer alters the physical characteristics, and it may be rather difficult to manufacture such a composite seal member in a certain shape. Moreover, the concern for peeling is not addressed in a definitive manner.

### SUMMARY OF THE INVENTION

Accordingly, an object of the present invention, having been completed by addressing the issues discussed above, is to provide a plasma processing apparatus component that does not readily deteriorate through a dry-cleaning process while sustaining the original physical characteristics of the organic material used to constitute the plasma processing apparatus component and a manufacturing method thereof.

The object described above is achieved in an aspect of the present invention by providing a plasma processing apparatus component installed within a processing chamber of a plasma processing apparatus that executes plasma processing on a substrate placed within the processing chamber by generating plasma inside the processing chamber, which is formed by executing surface fluoridation processing at a surface layer of an organic material (e.g., a rubber material or a resin material) that includes a carbon-hydrogen bond and is formed in a shape to be assumed by the component so as to substitute fluorine for the hydrogen bonded to the carbon contained in the surface layer.

Based upon the findings resulting from the tests and the like conducted by the inventor of the present invention et al., indicating that a component constituted with an organic material which includes a carbon-hydrogen bond deteriorates significantly through a dry-cleaning process and that fluoridation processing executed on the entire component actually adversely affects the original physical characteristics (tensile strength, shear strength, compressive strength and the like) of the component, surface fluoridation processing is executed only at the surface layer of the component so as to substitute fluorine for the hydrogen bonded to the carbon in the surface layer exclusively according to the present invention. Through these measures, the extent of deterioration occurring during the dry-cleaning process can be lessened to a significant extent without adversely affecting the original physical characteristics of the organic material constituting the plasma processing apparatus component.

In addition, the extent of deterioration occurring during the dry-cleaning process can be lessened to a sufficient extent through the surface fluoridation processing even when the component is constituted with an inexpensive organic material. Since the surface fluoridation processing according to the present invention is executed through substitution reaction, the shape of the component having undergone the surface fluoridation processing is not altered from the shape prior to the surface fluoridation processing as significantly as the shape of a component having undergone, for instance, addition reaction. Since this eliminates the need for processing the organic material prior to the surface fluoridation processing by estimating the dimensions thereof after the surface fluoridation processing, the organic material can be processed with greater ease prior to the surface fluoridation processing and moreover, the technology can be adopted effectively when forming a component assuming a complex shape.

It is desirable that the surface fluoridation processing for substituting fluorine for the hydrogen bonded to the carbon in the surface layer be executed by applying energy greater than, at least, the bonding energy with which carbon and hydrogen bond with each other to the surface layer of the organic material within a fluorine-containing gas atmosphere. Such energy may be applied via, for instance, a semiconductor laser or an electron beam. As the energy is applied to the surface layer of the organic material in the fluorine-containing gas atmosphere, as described above, and the bond between carbon and hydrogen in the surface layer is severed, the reaction progresses along a more energetically stable direction, allowing the fluorine bonding reaction to proceed without allowing the hydrogen to become re-bonded to the carbon. As a result, the efficiency of the surface fluoridation reaction is improved.

While the energy applied to the surface layer may be greater than the bonding energy with which carbon and fluorine bond with each other, it is more desirable to apply energy smaller than the carbon-fluorine bonding energy so as to lower the likelihood of the bond with the fluorine being severed and, therefore, assure more efficient surface layer fluoridation.

It is to be noted that dissociation of the fluorine and carbon is more likely to occur if the energy applied to the surface layer is greater than the carbon-hydrogen bonding energy and also greater than the carbon-fluorine bonding energy, the bond ultimately stabilizes in a fluoridated state. Namely, the process of fluoridation is ultimately promoted and thus, the surface layer of the organic material becomes fluoridated. However, it is obvious that the energy applied to the surface layer of the organic material still must be set lower than an energy level at which the organic material itself burns.

In addition, the surface fluoridation processing may be selectively executed on the part of the surface layer of the organic material that is exposed to the plasma. In this case, only a specific area of the surface layer of the organic material to constitute the component that needs to be treated through the surface fluoridation processing, assuring better efficiency in preventing component deterioration. Furthermore, since a greater portion of the surface layer remains untreated, the original physical characteristics of the organic material can be maintained intact more effectively. Such surface fluoridation processing may be executed by applying energy via, for instance, a semiconductor laser or an electron beam radiated on the specific area of the surface layer, to assure the ease with which the specific area of the surface layer of the organic material alone is fluoridated.

The organic material formed in the specific shape may be a rubber material formed in the shape of a seal member to be used to maintain the processing chamber in an airtight state. Since the extent of deterioration occurring during the dry-cleaning process can be reduced significantly and the physical characteristics including the sealability of the rubber material itself used to constitute the component such as a seal member can be sustained over an extended period of time, the service life of the rubber component can be extended.

Alternatively, the organic material formed in the specific shape may be a resin material formed in the shape of a shield member to be mounted at an electrode inside the processing chamber or a resin material formed in the shape of a fastening member to be used to fasten a component inside the processing chamber. Since the extent of deterioration occurring during the dry-cleaning process can be reduced significantly and the physical characteristics including the strength of the resin material itself used to constitute the component such as a shield member or a bolt can be sustained over an extended period of time, the service life of the resin component can be extended.

The object described above is also achieved in another embodiment of the present invention by providing a plasma processing apparatus component manufacturing method adopted when manufacturing a plasma processing apparatus component installed inside a processing chamber of a plasma processing apparatus that executes plasma processing on a substrate placed inside the processing chamber by generating plasma in the processing chamber, characterized in that energy is applied to a surface layer of an organic material that includes a carbon-hydrogen bond is formed in a specific shape and is exposed in a fluorine-containing gas atmosphere so as to substitute fluorine for the hydrogen bonded to the carbon in the surface layer. It is desirable that the energy be greater than the bonding energy with which carbon and hydrogen bond with each other. It is even more desirable that the energy be greater than the carbon-hydrogen bonding energy and smaller than the bonding energy with which carbon and fluorine bond with each other.

By adopting this method, a plasma processing apparatus component that does not readily deteriorate during the dry-cleaning process can be manufactured with ease without adversely affecting the original physical characteristics of the organic material constituting the component.

According to the present invention, the extent of deterioration occurring during the dry-cleaning process can be reduced significantly without compromising the original physical characteristics of the organic material constituting the plasma processing apparatus component. Furthermore, the deterioration occurring during the dry-cleaning process can be reduced to a sufficient extent through the surface fluoridation processing according to the present invention even when the plasma processing apparatus component is constituted with an inexpensive organic material.

### BRIEF DESCRIPTION OF THE DRAWINGS

FIG. 1 is a sectional view of the structure of a plasma processing apparatus that may include a component achieved in an embodiment of the present invention;

FIG. 2 presents the results of a dry-cleaning deterioration test in a diagram showing the relationship between the quantity of gas present inside the processing chamber during the dry-cleaning process and the extent of deterioration;

FIG. 3 presents the results of a dry-cleaning deterioration test in a diagram showing the relationship between the material constituting the component and the extent of deterioration;

FIG. 4 shows the relationships between specific component materials and pre-/post dry-cleaning physical characteristics;

FIG. 5 schematically illustrates an example of a structure that may be adopted in a surface processing apparatus engaged in surface fluoridation processing in the embodiment;

FIG. 6A is a conceptual diagram of a section of an O-ring yet to undergo the surface fluoridation processing in the embodiment;

FIG. 6B is a conceptual diagram of a section of an O-ring having undergone the surface fluoridation processing in the embodiment;

FIG. 7A is a conceptual diagram of a section of a shield ring yet to undergo the surface fluoridation processing in the embodiment; and

FIG. 7B is a conceptual diagram of a section of an shield ring having undergone the surface fluoridation processing in the embodiment.

### DETAILED DESCRIPTION OF THE PREFERRED EMBODIMENT

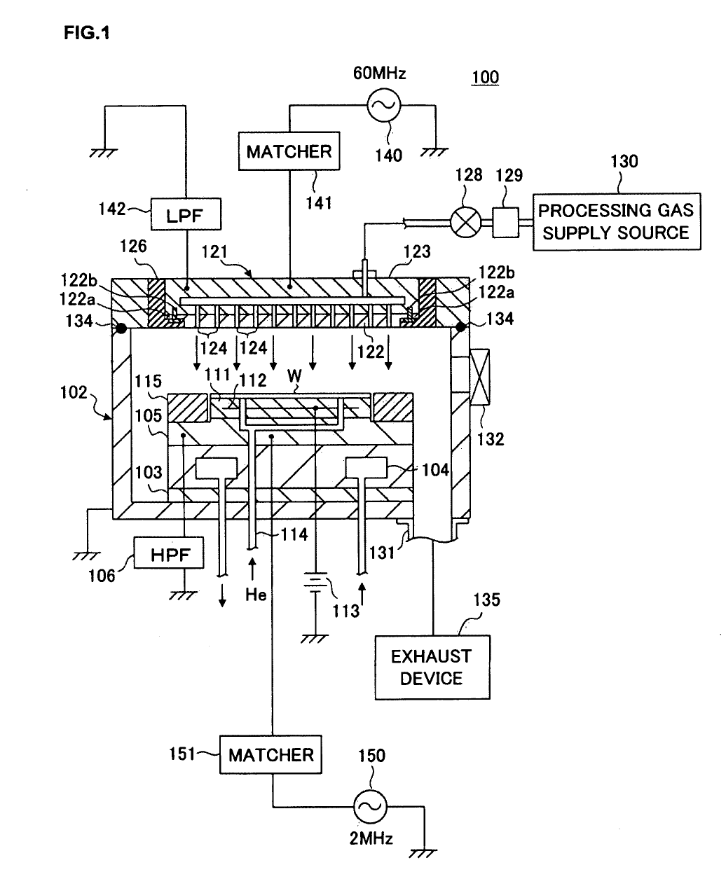

The following is a detailed explanation of a preferred embodiment of a plasma processing apparatus component and a manufacturing method thereof according to the present invention, given in reference to the attached drawings. A plasma processing apparatus that may include a component achieved in the embodiment is first described. FIG. 1 is a sectional view showing an example of a structure that may be adopted in the plasma processing apparatus. The explanation is provided by assuming that the plasma processing apparatus is a plane-parallel plasma etching apparatus.

### (Specific Example of Plasma Processing Apparatus)

A plasma processing apparatus 100 includes a processing chamber 102 constituted of an electrically conductive material such as aluminum, a lower electrode (susceptor) 105 disposed on the bottom surface within the processing chamber 102, on which a wafer W (i.e., the processing target substrate) is placed, and an upper electrode 121 disposed so as to face opposite and range parallel to the lower electrode 105, which also functions as a processing gas supply unit. A first high-frequency power source 150 is connected to the lower electrode 105 via a matcher 151, whereas a second high-frequency power source 140 assuming a higher frequency than the first high-frequency power source is connected to the upper electrode 121 via a matcher 141.

A processing gas supply source 130 is connected to the upper electrode 121 via a valves 128 and a mass flow controller 129 and the processing gas (e.g., a fluorocarbon gas (CₓF_{y}) used as an etching gas), the cleaning gas (e.g., O₂) and the like are supplied from the processing gas supply source 130 to the upper electrode 121.

It is to be noted that while FIG. 1 shows a single processing gas supply system constituted with the valve 128, the mass flow controller 129 and the processing gas supply source 130, the plasma processing apparatus 100 actually includes a plurality of processing gas supply systems. The flow rates of gases such as CF₄, O₂ and N₂ and CHF₃ are controlled independently of one another, as they are delivered into the processing chamber 102.

In addition, an exhaust port 131 is formed at the bottom surface of the processing chamber 102, and as the processing chamber 102 is evacuated via an exhaust device 135 connected to the exhaust port 131, the atmosphere within the processing chamber sustains a specific degree of vacuum via the processing gas.

As first high-frequency power at a frequency of 2 MHz is applied from the first high-frequency power source 150 to the lower electrode 105 and second high-frequency power with a frequency of 60 MHz is applied to the upper electrode 121 from the second high-frequency power sources 140 while the specific degree of vacuum is sustained inside the processing chamber 102 via the processing gas in the plasma processing apparatus 100 described above, plasma is generated from the processing gas in the space between the lower electrode 105 and the upper electrode 121 with the second high-frequency power and a self bias potential is generated at the lower electrode 105 with the first high-frequency power, thereby enabling plasma processing such as reactive ion etching to be executed on the wafer W placed on the lower electrode 105.

A focus ring 115 enclosing the wafer W along its periphery is mounted at the outer edge of the upper surface of the lower electrode 105 and plasma is directed onto the wafer W via the focus ring 115. An electrostatic chuck connected to a high-voltage DC power source 113 is disposed on the upper surface of the lower electrode 105, and the wafer W can be held fast onto the electrostatic chuck 111 with an electrostatic holding force generated as a high-voltage DC current is applied from the high-voltage DC power source 113 to an electrode 112 disposed inside the electrostatic chuck 111.

The lower electrode 105 includes a built-in temperature adjustment mechanism 104 used for temperature control and the temperature of the wafer W is adjusted to a predetermined level via the temperature adjustment mechanism 104. The temperature adjustment mechanism 104 adjusts the temperature of the lower electrode 105 by, for instance, circulating a coolant through a coolant chamber formed in the lower electrode 105. In addition, a gas passage 114, through which a heat transfer medium (e.g., He) is distributed, with a plurality of openings at the upper surface of the lower electrode, is formed inside the lower electrode 105. Holes are formed at the electrostatic chuck 111 each in correspondence to a gas passage opening. Thus, as the He gas is delivered to the narrow gap between the wafer W and the electrostatic chuck 111, heat transfer between the lower electrode 105 and the wafer W is promoted.

An insulating plate 103 is disposed between the lower surface of the lower electrode 105 and the bottom surface of the processing chamber 102, thereby insulating the lower electrode 105 and the processing chamber 102 from each other. It is to be noted that a bellows constituted of, for instance, aluminum, may be installed at the lower electrode 105 between the insulating plate 103 and the bottom surface of the processing chamber 102 so as to allow the lower electrode 105 to move up/down freely via an elevator mechanism (not shown). In such a case, the distance between the lower electrode and the upper electrode 121 can be adjusted as necessary in correspondence to the specific type of plasma processing to be executed.

The upper electrode 121 includes, for instance, a plate-type silicon electrode member 122 and a hollow aluminum supporting member 123 that detachably supports the electrode member 122. A thin portion 122a with a small wall thickness is formed on the entire outer edge of the electrode member 122 and the electrode member 122 is fastened onto the supporting member 123 over this thin portion 122a via bolts 122b. The bolts 122b are set over equal intervals along the edge of the thin portion 122a.

A shield ring 126 is mounted at the upper electrode 121. The shield ring 126 shields the outer peripheral surface of the upper electrode 121 and the thin portion 122a of the electrode member 122 and is set on the same plane as the electrode member 122 over the lower surface of the upper electrode 121. In addition, at the electrode member 122 and the lower surface of the supporting member 123 of the upper electrode 121, matching holes 124 are formed in a uniform array so as to deliver the processing gas received at the upper electrode 121 from the processing gas supply source 130 into the entire processing chamber 102 in the uniform dispersion.

It is to be noted that a high pass filter 106 that filters the high-frequency current flowing into the lower electrode 105 from the first high-frequency power source 150 is connected to the lower electrode 105, whereas a low pass filter 142 that filters the high-frequency current flowing into the upper electrode 121 from the second high-frequency power source 140 is connected to the upper electrode 121. A gate valve 132 is installed at the side wall of the processing chamber 102. Once this gate valve 132 opens, a wafer W can be carried into or out of the processing chamber 102. In addition, the ceiling at which the upper electrode 121 is mounted is used as a lid and can be opened/closed. A seal member 134 such as an O-ring is disposed between the lid and the side wall so as to sustain the processing chamber in an airtight state.

When dry etching a silicon oxide film, a silicon nitride film or polysilicon deposited on the surface of the wafer W in this plasma processing apparatus 100, a fluorine-containing gas such as CF₄ or CHF₃ is often used as the processing gas. During the etching process executed by using such a processing gas, the processing gas is raised to plasma thereby creating active seeds for ions, radicals and the like. SiF₄, CO₂ and the like resulting from the physical/chemical reactions of these active seeds with the silicon oxide film or the like exposed in a specific pattern are sequentially discharged to the outside of the processing chamber 102 for elimination by generating a volatile gas.

While the volatile gas is generated with the processing gas, reaction products constituted of fluorocarbon polymers (CF polymers) such as CₓF_{y}, CₓF_{y}O_{z} and the like are formed through, for instance, re-bonding of active seeds that have not been used in the reactions and these reaction products form a thin film as they settle and collect inside the processing chamber 102. As the etching process is repeatedly executed, this thin film gradually grows at the internal surface of the processing chamber 102 and the surfaces of the components disposed inside the processing chamber 102 until its film thickness becomes significant. The thin film subsequently peels off, creating particles. For this reason, the thin film is removed through regular cleaning. In this embodiment, the thin film constituted of CF polymers is removed through dry-cleaning with active seeds such as oxygen radicals (O*) formed by charging the processing chamber with oxygen gas and raising the gas to plasma with high-frequency power applied thereto. (Component deterioration occurring during the dry-cleaning process) As described above, there is an issue to be addressed in that during the dry-cleaning process executed to remove the reaction products such as CF polymers, certain components, too, deteriorate. The shield ring 126 used within the processing chamber 102 and the bolts 122b fastening the shield ring 126 are normally constituted with an organic resin such as polyimide, whereas the seal member 134 such as an O-ring is constituted of an organic rubber such as a fluorocarbon rubber.

It has been shown through testing and the like conducted by the inventor of the present invention et al. that components constituted of organic materials that include a carbon-hydrogen bond (C—H), e.g., polyimide and fluorocarbon rubber, are particularly prone to deterioration through the dry-cleaning process. Even if only oxygen gas is delivered into the processing chamber to clean the inside of the processing chamber with oxygen radicals (O*) during the dry-cleaning process, any presence of CF polymers inside the processing chamber 102 results in the formation of fluorine radicals (F*) during their removal. A small quantity of fluorine radicals mixed among the oxygen radicals is assumed to hasten the process of deterioration of the organic resin and rubber significantly as the components constituted with the organic materials which include the carbon-hydrogen bond (C—H) are exposed to these radicals and the reactive site reaction of the fluorine radicals to the carbon-hydrogen bond and the reaction of the oxygen radicals to free radicals become dominant.

The results of deterioration tests conducted on the polyimide resin by executing a dry-cleaning process on the polyimide resin are now described. In the tests, a plurality of silicon chips having a polyimide resist film formed at the surfaces thereof were attached at the inner wall of the processing chamber 102 and the processing chamber was dry-cleaned with oxygen gas.

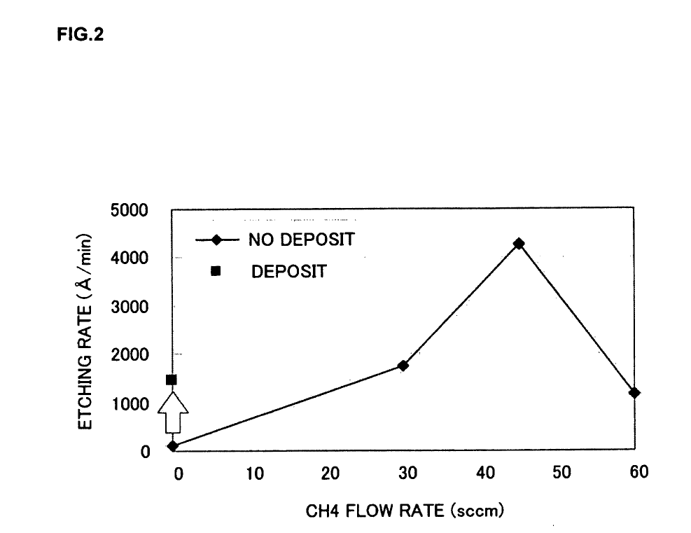

FIG. 2 presents the results of dry-cleaning tests conducted by generating plasma with the flow rate of the CF gas, e.g., CF₄ gas, adjusted to 0 sccm, 30 sccm, 45 sccm and 60 sccm in conjunction with oxygen gas supplied at a fixed flow rate of 600 sccm in a state in which no CF polymers had settled inside the processing chamber (no deposit). Since these tests were conducted with no CF polymers settled inside the processing chamber and thus, fluorine radicals were formed only from the CF₄ gas, the quantity of fluorine radicals could be adjusted in correspondence to the CF₄ gas flow rate.

FIG. 2 presents a graph obtained by detecting the resist film thicknesses of the resist film on the individual silicon chips before and after the dry-cleaning process executed with the varying flow rate ratios of the oxygen gas and the CF₄ gas and averaging the resist film thicknesses based upon the resist film etching rate (Å/min) per unit time (1 minute in this example). The graph indicates that the resist film deteriorated to a greater extent when the etching rate was higher.

The test results presented in FIG. 2 indicate that while the resist film deteriorated very little when the CF₄ gas flow rate was 0, i.e., when the oxygen gas alone was supplied into the processing chamber, the resist film deteriorated to a greater extent if a small quantity of CF₄ gas was present in the oxygen gas.

Namely, up to a CF₄ gas flow rate of approximately 45 sccm, the resist film deteriorates to a greater extent as the quantity of CF₄ gas supplied into the processing chamber increases. However, once the CF₄ gas flow rate exceeds 45 sccm, the extent of the resist film deterioration become smaller. In other words, if the CF₄ gas flow rate is too high relative to the oxygen gas flow rate, the resist film does not readily deteriorate, the resist film deteriorates to a significant extent if a small amount of CF₄ gas is present in the oxygen gas.

The resist film deterioration extent increases until the flow rate ratio (CF₄ gas flow rate/oxygen gas flow rate) of the oxygen gas and the CF₄ gas reaches approximately 40 sccm/600 sccm. Under such circumstances, fluorine radicals are formed in the quantity substantially equal to the quantity of fluorine radicals formed while dry-cleaning the inside of the processing chamber 100 where CF polymers have settled. This means that the components deteriorate significantly through the dry-cleaning process.

FIG. 2 also presents the results of dry-cleaning tests conducted without drawing in any CF gas with the oxygen gas flow rate fixed at 600 sccm in the processing chamber 102 where CF polymers had settled (deposit). The results indicate that if CF polymers had settled inside the processing chamber, the resist film deteriorated to a great extent even without the processing chamber being charged with any CF gas. This deterioration of the resist film is attributable to a very small amount of fluorine radicals formed as the CF polymers were removed.

As described above, any component constituted of an organic material that includes a carbon-hydrogen bond (C—H) is particularly likely to deteriorate through the dry-cleaning process. This means that while resin components, e.g., the shield ring 126 and the bolts 122b, constituted of an organic resin material such as polyimide, assure superior physical characteristics including the strength, they tend to deteriorate significantly during the dry-cleaning process. For this reason, the resin components may instead be constituted of a Teflon® resin, which does not include a carbon-hydrogen bond (C—H), so as to prevent significant deterioration during the dry-cleaning process. However, the Teflon® resin does not normally assure superior strength and thus cannot be used as the base material for components that need a high level of strength such as bolts. In addition, the Teflon® resin is normally fairly expensive and thus, the manufacturing costs is bound to be high.

Rubber components such as the seal member 134 are normally formed by using fluorocarbon rubber (fluoroelastomer), for optimal balance between the cost and the desirable physical characteristics including the plasma resistance characteristics. In recent years, the use of fully fluoridated rubber (parfluoroelastomer) providing plasma resistance characteristics superior to regular fluorocarbon rubber (fluoroelastomer) has become more common.

The molecular structure of the standard fluorocarbon rubber is indicated in chemical expression (1), whereas the molecular structure of the fully fluoridated rubber is indicated in chemical expression (2) below. Chemical expression (1) describes the molecular structure of FKM, i.e. the fluoroelastomer, whereas chemical expression (2) describes the molecular structure of FFKM, i.e., a parfluoroelastomer.

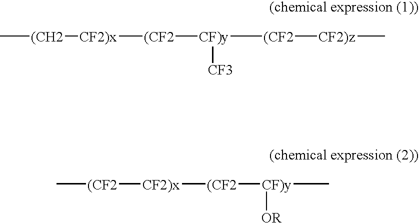

While the standard fluorocarbon rubber (FKM) includes a carbon-hydrogen bond (C—H) in the principal chain thereof as indicated in chemical expression (1), the principal chain in the fully fluoridated rubber (FFKM) is entirely constituted with a carbon-fluorine bond (C—F) as indicated in the chemical expression (2). This means that while the standard fluorocarbon rubber (FKM) provides superior physical characteristics including the sealability, it tends to deteriorate markedly through the dry-cleaning processed due to the presence of the carbon-hydrogen bond (C—H). In contrast, the fully fluoridated rubber (FFKM) does not include a carbon-hydrogen bond (C—H) in the principal chain thereof, which may lead to the expectation that a rubber component such as an O-ring constituted of fully fluoridated rubber will not deteriorate significantly during the dry-cleaning process. However, the fully fluoridated rubber, with its principal chain constituted with the carbon-fluorine bond (C—F) has physical characteristics similar to those of the Teflon® material, including poor shielding property. In addition, it is much more expensive than the standard fluorocarbon rubber, and the use of the fully fluoridated rubber is bound to increase the manufacturing costs.

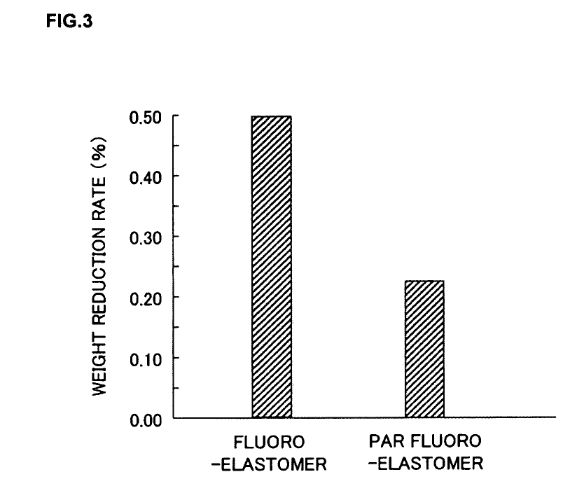

The results of dry-cleaning deterioration tests conducted by using the standard fluorocarbon rubber (fluoroelastomer) and the fully fluoridated rubber (parfluoroelastomer) are now described. The dry-cleaning process was executed in processing chambers with O-rings constituted of the standard fluorocarbon rubber (fluoroelastomer) O-rings constituted of fully fluoridated rubber (parfluoroelastomer) installed therein by generating plasma with oxygen gas and CF₄ gas supplied at 1400 sccm and 20 sccm respectively into the processing chambers with no CF polymers having settled therein. FIG. 3 presents bar graphs each indicating the extent by which the weight of each O-ring decreased after the dry-cleaning process executed over a specific length of time (100 hours), relative to the pre-dry-cleaning O-ring weight.

FIG. 3 indicates that the parfluoroelastomer weight reduction rate is half or less than half the fluoroelastomer weight reduction rate. In other words, it indicates that the parfluoroelastomer does not deteriorate during the dry-cleaning process as much as the fluoroelastomer.

It is to be noted that even the parfluoroelastomer does deteriorate to a certain extent during the dry-cleaning process. This deterioration is assumed to be attributable to the following; while no carbon-hydrogen bond (C—H) is present in the principal chain of the parfluoroelastomer, the carbon-hydrogen bond (C—H) remains in the bridging portion and deterioration occurs in this area through the reactive site reaction of fluorine radicals to a carbon-hydrogen bond and the reaction of oxygen radicals to free radicals.

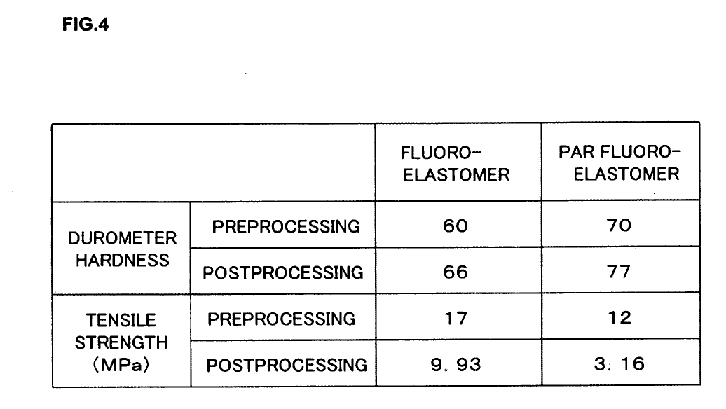

In addition, FIG. 4 presents the physical characteristics of the O-ring constituted with a standard fluorocarbon rubber (fluoroelastomer) and the O-ring constituted of fully fluoridated rubber (parfluoroelastomer), measured before and after the dry-cleaning process. The physical characteristics were measured by conducting hardness tests and tensile strength tests. The hardness levels are indicated by the values obtained through measurement executed by using a hardness durometer (shore hardness tester) which is a spring-type hardness tester. The tensile strength level is indicated by values obtained through measurement of the stress required to rupture the rubber materials in the tensile strength test.

FIG. 4 indicates that no significant change occurred in the hardness of either the fluoroelastomer or the parfluoroelastomer after the dry-cleaning process relative to the pre-dry-cleaning hardness level. However, while the tensile strength of the fluoroelastomer decreased to approximately ½ of its pre-dry-cleaning tensile strength, the tensile strength of the parfluoroelastomer decreased more significantly to ¼ of the pre-dry-cleaning tensile strength. This means that the sealability of the parfluoroelastomer is reduced more significantly through the dry-cleaning process than the sealability of the fluoroelastomer.

These test results confirmed that a rubber component such as an O-ring, entirely constituted with a standard fluorocarbon rubber, is bound to deteriorate significantly during the dry-cleaning and that while a rubber component, entirely constituted with the fully fluoridated rubber, does not deteriorate as readily, its physical characteristics including the sealability are seriously compromised through the dry-cleaning process. In addition, while a resin component entirely constituted with a polyimide resin or the like deteriorates significantly during the dry-cleaning process a resin component entirely constituted with a Teflon® resin does not deteriorate as readily but the Teflon resin is not a suitable material to constitute a component that needs a high level of strength.

### (Component Achieved in the Embodiment and Manufacturing Method Thereof)

According to the present invention, a rubber component or a resin component in the plasma processing apparatus described above is formed by using an organic material (rubber or resin) that includes a carbon-hydrogen bond achieving the required physical characteristics (e.g., the required tensile strength, shear strength, compressive strength and the like) and surface fluoridation processing is executed on the surface layer of the organic material to substitute fluorine for the hydrogen bonded to the carbon in the surface layer. The resulting rubber component or resin component does not deteriorate readily during the dry-cleaning process while sustaining the original physical characteristics of the organic materials.

The surface fluoridation processing may be executed by placing an organic material formed in the shape to be assumed by the rubber component or a resin component in a fluorine-containing gas (e.g., fluorine gas) atmosphere. As energy greater than, at least, the bonding energy with which carbon and hydrogen bond with each other is applied to the surface layer of the organic material in this state, the hydrogen bonded to the carbon in the surface layer is replaced with fluorine. As the energy is applied to the surface layer of the organic material placed in the fluorine-containing gas atmosphere as described above, and the bond between carbon and hydrogen in the surface layer is severed, the reaction progresses along a more energetically stable direction, allowing the fluorine bonding reaction to proceed without allowing the hydrogen to become re-bonded to the carbon. As a result, the efficiency of the surface fluoridation reaction is improved.

While the energy applied to the surface layer of the organic material in this situation may be greater than the carbon-hydrogen bonding energy and also greater than the carbon-fluorine bonding energy, the likelihood of severing the fluorine that has become bonded to the carbon can be lowered by applying energy greater than the carbon-hydrogen bonding energy but smaller than the carbon-fluorine bonding energy so as to fluoridate the surface layer more efficiently.

It is to be noted that while dissociation of the fluorine and carbon is more likely to occur if the energy applied to the surface layer is greater than the carbon-hydrogen bonding energy and also greater than the carbon-fluorine bonding energy, the bond ultimately stabilizes in a fluoridated state. Namely, the process of fluoridation is ultimately promoted and thus, the surface layer of the organic material becomes fluoridated. However, it is obvious that the energy applied to the surface layer of the organic material still must be set lower than an energy level at which the organic material itself burns.

In addition, it is desirable that the energy be provided via semiconductor laser or an electron beam. Such a semiconductor laser may be, for instance, an Excimer laser. By using energy provided via an Excimer laser, which is greater than the carbon-hydrogen bonding energy but smaller than the carbon-fluorine bonding energy, the likelihood of severing the fluoridation bond is reduced so as to fluoridate the surface layer with a higher level of efficiency.

Furthermore, by using a semiconductor laser or an electron beam, surface fluoridation processing can be selectively executed over a specific area of the surface layer of the organic material formed in the shape to be assumed for the rubber component or the resin component. For instance, by applying energy with a semiconductor laser or an electron beam radiated over the specific area of the surface layer of the organic material, only the necessary portion of the surface layer of the organic material can be fluoridated with ease. Thus, the surface fluoridation processing can be executed on, for instance, a portion exposed to the plasma only.

Moreover, the surface fluoridation processing in the embodiment, which can be executed on the surface of the organic material after forming it in the desired shape, can be adopted when manufacturing a component with a complex shape as well.

It is to be noted that surface fluoridation processing other than that described above may be executed as long as the surface layer of the organic material alone can be fluoridated through the processing. For instance, an organic resin material may be irradiated with a semiconductor laser or an electron beam in the gas atmosphere as described above or it may be soaked in a fluorine solvent and be irradiated with a semiconductor laser or an electron beam. Since the resin soaked in the fluorine-group solvent will not become swollen, the initially-formed shape will be maintained.

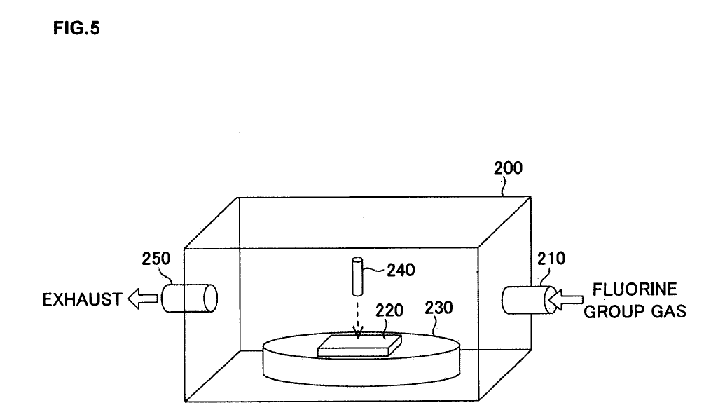

FIG. 5 presents an example of a structure that may be adopted in a surface processing apparatus engaged in surface fluoridation processing executed in a fluorine-containing gas atmosphere by using a semiconductor laser. The surface processing apparatus comprises an airtight processing chamber 200, a gas delivery system 210 through which a fluorine-containing gas is delivered into the processing chamber 200, a stage 230 on which a processing target workpiece 220 to undergo the surface processing is placed, a semiconductor laser 240 that radiates laser light onto a surface layer of the processing target workpiece and an exhaust system 250 connected to an exhaust device (not shown) that discharges gas from the processing chamber. The semiconductor laser 240 is disposed so that it is able to move freely along the horizontal direction (the XY direction) to radiate the laser light onto the surface layer of the processing target workpiece 220 at a desired position. It is to be noted that a heater may be installed at the stage 230 and the energy applied to the processing target workpiece 220 may be supplemented with thermal energy applied via the heater to the processing target workpiece 220. In such a case, the length of processing time can be reduced.

At the surface processing apparatus, a fluorine-containing gas, for instance, is delivered into the processing chamber 200 in which the processing target workpiece 220 is placed upon the stage 230. As the processing chamber 200 becomes filled with the fluorine-containing gas, laser light from the semiconductor laser is radiated onto the surface layer of the processing target workpiece 220. The hydrogen bonded to the carbon in the surface layer becomes replaced by fluorine as the laser light irradiates the surface layer.

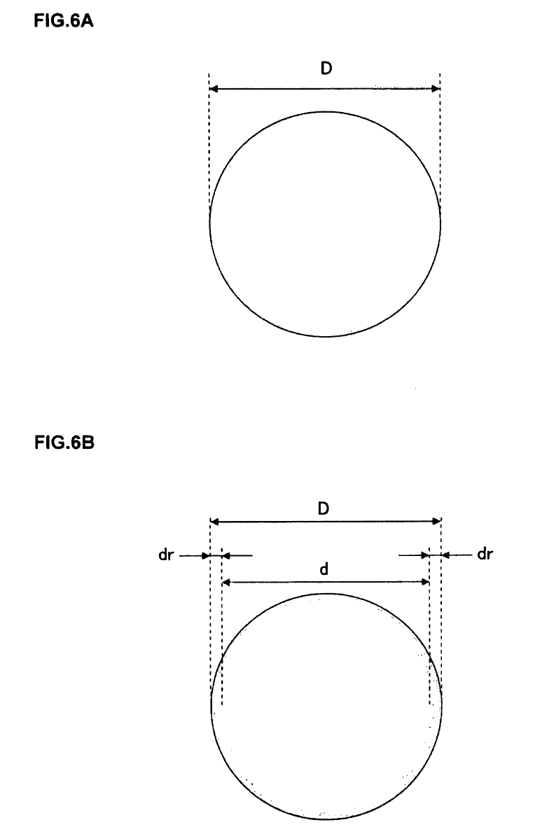

An explanation is now given on the surface fluoridation processing in the embodiment adopted to process an O-ring representing an example of a rubber component such as the seal member 134. FIG. 6A presents a conceptual diagram of a section of the O-ring yet to undergo the surface fluoridation processing and FIG. 6B presents a conceptual diagram of a section of the O-ring having undergone the surface fluoridation processing. The O-ring with a diameter D in FIG. 6A is constituted of standard fluorocarbon rubber (fluoroelastomer) assuring good sealability and available at low cost. After the surface fluoridation processing executed over the entire surface layer of this O-ring, an alteration in the molecular structure occurs through fluorine substitution for the hydrogen bonded to the carbon only at the surface layer (to a depth dr) having undergone the surface fluoridation processing alone, without altering the molecular structure of the substance further inward relative to the surface layer (the area with a diameter d, as shown in FIG. 6B. As a result, there is no longer any carbon-hydrogen bond present in the surface layer (to the depth dr) that is exposed to oxygen radicals and fluorine radicals formed during the dry-cleaning process, which means that overall deterioration in the O-ring can be prevented to a satisfactory degree even when it is constituted of an inexpensive material. In addition, since the molecular structure remains unaltered further inward relative to the surface layer (the area with the diameter d), the physical characteristics of the O-ring including the sealability are maintained intact.

Since the surface fluoridation processing in the embodiment is achieved through a substitution reaction whereby hydrogen bonded to the carbon becomes substituted with fluorine, the diameter D of the O-ring remains unchanged even after the surface fluoridation processing. In contrast, following fluoridation achieved through an addition reaction whereby fluorine is coated onto the surface layer, as in the related art, the shape of the O-ring is naturally likely to be altered, including an increase in the diameter D. For this reason, the thickness of the fluorine coating must be minimized and thus, the depth to which the surface is fluoridated cannot be controlled.

The diameter of the O-ring having undergone the surface fluoridation processing in the embodiment achieved through the substitution reaction described above, on the other hand, does not increase, which enables easy adjustment of the depth to which the surface layer is to be fluoridated. For instance, provided that the surface fluoridation processing is executed by using a semiconductor laser, the depth to which the surface layer is fluoridated can be adjusted with ease by adjusting the intensity of the semiconductor laser light or the length of time over which the laser light is radiated.

In addition, if the entire component constituted of an organic material that includes a carbon-hydrogen bond is fluoridated, i.e., if the inner portion as well as the surface portion of the component is fluoridated, the permeability of the component to the processing gas and the like are bound to increase. However, only the surface layer of the component is fluoridated through the surface fluoridation processing in the embodiment and thus, the gas permeability of the entire component can be kept at a lower level.

It is to be noted that the rubber component achieved by adopting the present invention is not limited to a seal member such as the O-ring described above and the present invention can be adopted in any rubber component that may deteriorate through the dry-cleaning process. In addition, the fluorocarbon rubber used as the organic material to constitute the rubber component is not limited to the vinylidene fluoride rubber (FKM) or tetrafluoroethylene parfluorovynilether rubber (FFKM) mentioned earlier and the surface fluoridation processing may instead be executed on a component constituted of, for instance, tetrafluoroethylene propylene rubber (FEPM).

In addition, an organic rubber material other than fluorocarbon rubber may be used to constitute the rubber component, as long as the organic material includes a carbon-hydrogen bond and has the physical characteristics required for the rubber component. For instance, the present invention may be adopted in conjunction with a nitrile rubber (NBR), ethylene propylene diene monomer rubber (EPDM) or the like.

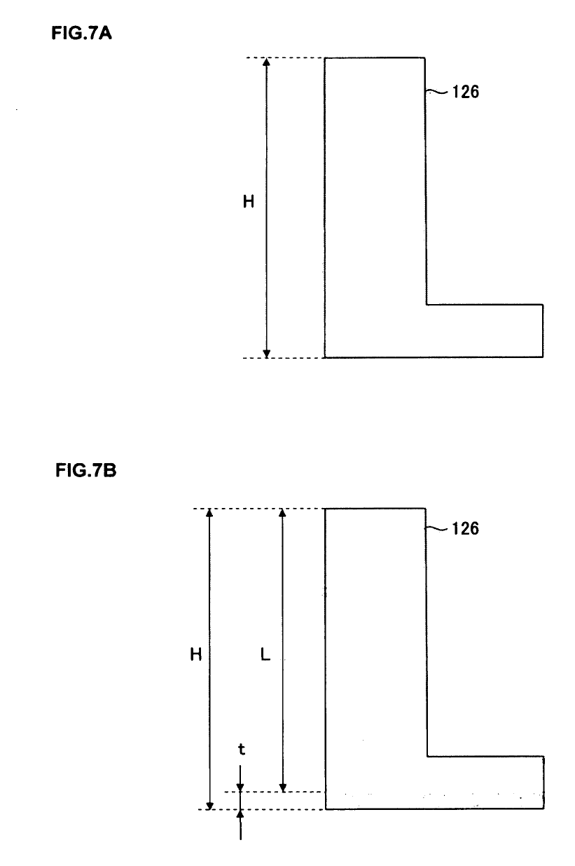

An explanation is now given on the surface fluoridation processing in the embodiment adopted to process a resin component such as the shield ring 126. FIG. 7A presents a conceptual diagram of a section of the shield ring yet to undergo the surface fluoridation processing and FIG. 7B presents a conceptual diagram of a section of the shield ring having undergone the surface fluoridation processing. The surface fluoridation processing may be executed over the entire surface of the component as in the case of the surface fluoridation processing shown in FIGS. 6A and 6B, or it may be executed selectively over part of the surface of the component. An explanation is now given on an example in which the surface fluoridation processing is executed over part of the surface of the shield ring 126.

The shield ring 126 assuming a height H, as shown in FIG. 7A may be formed by using a polyimide. As the surface fluoridation processing is executed only over part of the surface layer (over the bottom surface) of the shield ring 126, which is exposed to the plasma, the molecular structure becomes altered only at the surface layer (to the depth t) having undergone the surface fluoridation processing, with the hydrogen having been bonded to the carbon becoming substituted with fluorine, while the molecular structure in the portion above the surface layer (the portion with a height L) remaining unaltered, as shown in FIG. 7B.

Since the hydrogen bonded to the carbon has been substituted by fluorine in the surface layer at the lower surface, which is exposed to the plasma when the shield ring 126 is dry-cleaned, the deterioration of the shield ring 126 constituted of an inexpensive material can be reduced to an acceptable extent. Since the shield ring 126 is not fluoridated in its entirety, the physical characteristics of the shield ring 126 are maintained intact.

It is to be noted that the present invention may be adopted in a resin component other than the shield ring 126 described above and that it may be adopted in any of various other resin components including the bolts 122b used to fasten the shield ring, that may deteriorate during the dry-cleaning process. In addition, the organic material used to manufacture the resin component is not limited to the polyimide resin mentioned above and any of various other organic materials that include a carbon-hydrogen bond and assume the physical characteristics required for the resin component may be used. The organic material to undergo the surface fluoridation processing may be, for instance, a poly ether ketone (PEEK) resin, an acrylic resin, a polyca (PEC) resin or a polybenzimidazole (PBI) resin.

While the invention has been particularly shown and described with respect to a preferred embodiment thereof by referring to the attached drawings, the present invention is not limited to this example and it will be understood by those skilled in the art that various changes in form and detail may be made therein without departing from the spirit, scope and teaching of the invention.

What is claimed is:

1. A plasma processing apparatus component installed within a processing chamber of a plasma processing apparatus that executes plasma processing on a substrate placed within said processing chamber by generating plasma inside said processing chamber, wherein:
said component is formed by executing surface fluoridation processing at a surface layer of an organic material that includes a carbon-hydrogen bond and is formed in a shape to be assumed by said component so as to substitute fluorine for the hydrogen bonded to the carbon contained in said surface layer.

2. A plasma processing apparatus component according to claim 1, wherein:
said surface fluoridation processing for substituting fluorine for the hydrogen bonded to the carbon in said surface layer is executed by applying energy greater than, at least, the bonding energy with which carbon and hydrogen bond with each other to said surface layer of said organic material within a fluorine-containing gas atmosphere.

3. A plasma processing apparatus component according to claim 2, wherein:
said energy applied to said surface layer of said organic material is greater than the bonding energy with which carbon and hydrogen bond with each other but smaller than the bonding energy with which carbon and fluorine bond with each other.

4. A plasma processing apparatus component according to claim 3, wherein:
said energy is provided via a semiconductor laser or an electron beam.

5. A plasma processing apparatus component according to claim 1, wherein:
said surface fluoridation processing is selectively executed on part of said surface layer of said organic material that is exposed to the plasma.

6. A plasma processing apparatus component according to claim 1, wherein:
said organic material is a rubber material or a resin material.

7. A plasma processing apparatus component according to claim 1, wherein:
said organic material formed in the specific shape is a rubber material formed in the shape of a seal member to be used to maintain said processing chamber in an airtight state

8. A plasma processing apparatus component according to claim 1, wherein:
said organic material formed in the specific shape is a resin material formed in the shape of a shield member to be mounted at an electrode inside said processing chamber.

9. A plasma processing apparatus component according to claim 1, wherein:
said organic material formed in the specific shape is a resin material formed in the shape of a fastening member to be used to fasten a component inside said processing chamber

10. A plasma processing apparatus component manufacturing method adopted when manufacturing a component installed inside a processing chamber of a plasma processing apparatus that executes plasma processing on a substrate placed inside said processing chamber by generating plasma in said processing chamber, wherein:
energy is applied to a surface layer of an organic material that includes a carbon-hydrogen bond is formed in a specific shape and is exposed in a fluorine-containing gas atmosphere so as to substitute fluorine for the hydrogen bonded to the carbon in said surface layer.

11. A plasma processing apparatus component manufacturing method according to claim 10, wherein:
said energy is greater than the bonding energy with which carbon and hydrogen bond with each other.

12. A plasma processing apparatus component manufacturing method according to claim 11, wherein:
said energy is greater than the carbon-hydrogen bonding energy and smaller than the bonding energy with which carbon and fluorine bond with each other.
